(19) United States
(12) Patent Application Publication
(10) Pub. No.: US 2026/0371658 A1
(43) Pub. Date: Nov. 19, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Donghoon KIM, Suwon-si (KR); Sijung YOO, Suwon-si (KR); Dukhyun CHOE, Suwon-si (KR)

(73) Assignee: Samsung Electronics Co., Ltd., Suwon-si (KR)

(21) Appl. No.: 19/671,541

(22) Filed: May 8, 2026

(30) Foreign Application Priority Data
May 15, 2025 (KR) 10-2025-0063515

(51) Int. Cl. H10D 30/69; H10B 43/27

(52) U.S. Cl. CPC H10D 30/701; H10B 43/27; H10D 30/691

(57) ABSTRACT

A semiconductor device includes a channel, a gate electrode, a ferroelectric layer between the channel and the gate electrode, and a charge trap layer including a first trap layer and a second trap layer, wherein the first trap layer is located between the ferroelectric layer and the gate electrode, and the second trap layer is located between the first trap layer and the gate electrode, wherein the first trap layer, the second trap layer, and the ferroelectric layer include at least one identical element other than oxygen.

### CROSS-REFERENCE TO RELATED APPLICATION

This application is based on and claims priority under 35 U.S.C. § 119 to Korean Patent Application No. 10-2025-0063515, filed on May 15, 2025, in the Korean Intellectual Property Office, the disclosure of which is incorporated by reference herein in its entirety.

### BACKGROUND

### 1. Field

The present disclosure relates to a semiconductor device and a method of manufacturing the same.

### 2. Description of the Related Art

Transistors are semiconductor devices that are configured to perform electrical switching functions and are used in various semiconductor products, such as memory and drive integrated circuits (ICs). As the sizes of semiconductor devices are reduced, the number of semiconductor devices that may be integrated into a single wafer increases, and the demand for faster operating speeds of the semiconductor devices has also increase; accordingly, research is actively being conducted to reduce the size of semiconductor devices and the improve the operating speeds thereof.

### SUMMARY

Recently, hafnia (HfO₂), which is a high-k material, has been in the spotlight for reducing the size of semiconductor devices. Because doped HfO₂ may have ferroelectricity, hafnia is being researched for use in ferroelectric transistors (FeFETs). However, for a FeFET utilizing HfO₂, research for increasing a memory window, which may not be sufficiently secured as compared to other charge trap flash-based devices, is being conducted. Further, in order to maintain stable performance without device deterioration, research for increasing the thermal stability is also being explored. Accordingly, in the present disclosure, a semiconductor device and a method of manufacturing a semiconductor device are provided.

Additional aspects will be set forth in part in the description which follows and, in part, will be apparent from the description, or may be learned by practice of the presented embodiments of the disclosure.

According to an aspect of the disclosure, a semiconductor device includes a channel, a gate electrode, a ferroelectric layer between the channel and the gate electrode, and a charge trap layer including a first trap layer and a second trap layer, the first trap layer between the ferroelectric layer and the gate electrode and in direct contact with the ferroelectric layer, and the second trap layer between the first trap layer and the gate electrode and in direct contact with the first trap layer, wherein the first trap layer, the second trap layer, and the ferroelectric layer include at least one identical element other than oxygen.

The second trap layer may include a first material, and the ferroelectric layer may include the material and a first dopant.

The first dopant may include at least one of zirconium (Zr), lanthanum (La), aluminum (Al), silicon (Si), and yttrium (Y).

A doping concentration of the ferroelectric layer may be 10 at % to 90 at %.

The second trap layer may include a first material, and the first trap layer may include the material and a second dopant.

The second dopant may include at least one of zirconium (Zr), lanthanum (La), aluminum (Al), silicon (Si), and yttrium (Y).

A doping concentration of the first trap layer may be 50 at % or more.

The ferroelectric layer and the first trap layer may have different dopants.

The ferroelectric layer may include a plurality of first material layers and at least one second material layer, the at least one second material layer may be between two of the plurality first material layers which are facing each other, and each of the plurality of first material layers may include a ferroelectric material, and the at least one second material layer includes a paraelectric material.

A thickness of the ferroelectric layer may be greater than a thickness of the charge trap layer.

The semiconductor device may further include a first insulating layer between the channel and the ferroelectric layer.

The semiconductor device may further include a second insulating layer between the charge trap layer and the gate electrode.

The first trap layer, the second trap layer, and the ferroelectric layer may each include hafnium.

The ferroelectric layer may include hafnium zirconium oxide, the first trap layer may include hafnium aluminum oxide, and the second trap layer may include hafnium oxide.

According to another aspect of the disclosure, a semiconductor device includes a channel, a gate electrode, a ferroelectric layer between the channel and the gate electrode, and a charge trap layer including a first trap layer and a second trap layer, the first trap layer between the ferroelectric layer and the gate electrode and in direct contact with the ferroelectric layer, and the second trap layer between the first trap layer and the gate electrode and in direct contact with the first trap layer, wherein a permittivity of the first trap layer is less than a permittivity of the ferroelectric layer and the permittivity of the first trap layer is less than is less than a permittivity of the second trap layer.

The permittivity of the second trap layer may be less than the permittivity of the ferroelectric layer.

The semiconductor device may further include a first insulating layer between the channel and the ferroelectric layer.

The semiconductor device may further include a second insulating layer between the charge trap layer and the gate electrode.

The first trap layer, the second trap layer, and the ferroelectric layer may each include hafnium.

The ferroelectric layer may include hafnium zirconium oxide, the first trap layer may include hafnium aluminum oxide, and the second trap layer may include hafnium oxide.

According to another aspect of the disclosure, a method of manufacturing a semiconductor device includes preparing a channel, forming a ferroelectric material on the channel, forming a ferroelectric layer by crystallizing the ferroelectric material, forming a first trap layer in contact with the ferroelectric layer, forming a second trap layer in contact with the first trap layer, and forming a gate electrode on the second trap layer, wherein the first trap layer, the second trap layer, and the ferroelectric layer may include at least one identical element except oxygen.

A permittivity of the first trap layer may be less than a permittivity of the ferroelectric layer and a permittivity of the second trap layer.

The method of manufacturing the semiconductor device may further include forming a first insulating layer between the channel and the ferroelectric layer.

The method of manufacturing the semiconductor device may further include forming a second insulating layer between the charge trap layer and the gate electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating a semiconductor device according to at least one example embodiment;

FIG. 2 is a graph for comparing the permittivity of a charge trap layer and a ferroelectric layer of a semiconductor device according to at least one example embodiment;

FIG. 3 is a view illustrating a semiconductor device according to at least one example embodiment;

FIG. 4 is a flowchart illustrating a method of manufacturing a semiconductor device, according to at least one example embodiment;

FIG. 5 is a cross-sectional view illustrating a schematic structure of a memory device according to at least one example embodiment;

FIG. 6 is a cross-sectional view taken along line A-A′ of FIG. 5;

FIG. 7 is a flowchart illustrating a method of manufacturing a memory device, according to another embodiment;

FIG. 8 is a perspective view illustrating a memory device according to at least one example embodiment;

FIG. 9 is a diagram illustrating an electronic component according to at least one example embodiment; and

FIG. 10 is a diagram illustrating an electronic component according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and a method of manufacturing the same according to various embodiments are described in detail with reference to the attached drawings. In the following drawings, the same reference numerals refer to the same components, and a size of each component in the drawings may be exaggerated for the sake of clear and convenient description. Also, the following embodiments to be described are merely examples, and various modifications may be made from the embodiments. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical and/or geometric values.

Hereinafter, what is described as an “upper portion” or “on, over, or above” may also include not only “on” but also “above” and “over”. Singular expressions include plural expressions unless the context clearly indicates otherwise. In addition, when a portion “includes” a certain component, this means that other components may be further included rather than excluding other components unless specifically stated to the contrary. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

Use of a term “the” and similar reference terms may correspond to both the singular and the plural. Steps constituting a method may be performed in any suitable order unless there is a clear statement that the steps should be performed in the order described or contrary to the order and are not limited thereto.

Also, the use of terms like “ . . . unit”, “ . . . module”, etc., which are used herein to specify am element for processing at least one function or operation, may be implemented with and/or include processing circuitry such as hardware or software or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. Connection or connection members of lines between configuration elements illustrated in the drawings exemplarily represent functional connections and/or physical or circuit connections and may be represented as alternative or additional various functional connections, physical connections, or circuit connections in an actual apparatus.

Use of all examples or all example terms is merely for describing technical ideas in detail, and the scope of claims is not limited by the examples or the example terms unless limited by the claims.

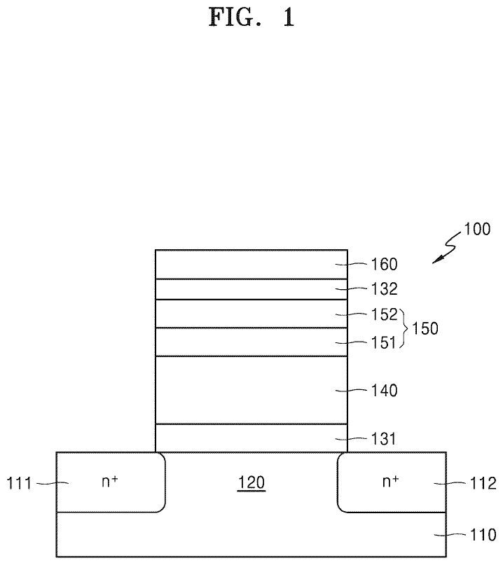

FIG. 1 is a view illustrating a semiconductor device according to at least one example embodiment.

Referring to FIG. 1, a semiconductor device 100 may include a source region 111, a drain region 112, a channel 120 between the source region 111 and the drain region 112, a gate electrode 160, a ferroelectric layer 140 between the channel 120 and the gate electrode 160, and a charge trap layer 150 including a first trap layer 151 between the ferroelectric layer 140 and the gate electrode 160, and a second trap layer 152 between the first trap layer 151 and the gate electrode 160. In addition, the semiconductor device 100 may further include a first insulating layer 131 between the channel 120 and the ferroelectric layer 140, and a second insulating layer 132 between the charge trap layer 150 and the gate electrode 160. That is, the first insulating layer 131 may be on an upper surface of the channel 120, the ferroelectric layer 140 may be on an upper surface of the first insulating layer 131, the charge trap layer 150 may be on an upper surface of the ferroelectric layer 140, the second insulating layer 132 may be on an upper surface of the charge trap layer 150, and the gate electrode 160 may be on an upper surface of the second insulating layer 132. In at least one example embodiment, the semiconductor device 100 may be referred to as having a gate stack including the gate electrode 160, the ferroelectric layer 140, the charge trap layer 150, and the first and second insulating layers 131 and 132.

The semiconductor device 100 may further include a substrate 110. The source region 111 and the drain region 112 may be arranged on both sides of an upper portion of the substrate 110. The channel 120 may be part of the upper portion of the substrate 110. Although not illustrated in FIG. 1, the semiconductor device 100 may further include a source electrode and a drain electrode respectively arranged on the source region 111 and the drain region 112.

In at least one example embodiment, the source region 111 and the drain region 112 may be doped with a first conductivity type, and the substrate 110 may be doped with a second conductivity type that is electrically opposite to the first conductivity type. For example, the substrate 110 may include a p-type semiconductor and the source region 111 and the drain region 112 may include an n-type semiconductor, or the substrate 110 may include an n-type semiconductor and the source region 111 and the drain region 112 may include a p-type semiconductor. The substrate 110 may be doped at a relatively low concentration of about 10¹⁶ to 10¹⁷/cm³, while the source region 111 and the drain region 112 may be doped at a relatively high concentration of about 10¹⁹ to 10²¹/cm³ for a lower resistance. In other words, the doping of the substrate 110 may result in the substrate 110 and/or the channel 120 having a higher resistance compared to the source region 111 and the drain region 112. The source region 111 and the drain region 112 may be formed by respectively doping both sides of the channel 120 on the upper portion of the substrate 110. Thereby, in at least some embodiments, the channel 120 may be defined by the source region 111 and the drain region 112. In at least one embodiment, the upper region of the substrate 110, in which the source region 111 and the drain region 112 are not formed, may be the channel 120. Therefore, the channel 120 may be arranged between the source region 111 and the drain region 112 in the upper region of the substrate 110.

The substrate 110, the channel 120, the source region 111, and the drain region 112 may include at least one semiconductor material. The at least one semiconductor material may be, for example, an elemental semiconductor (e.g., a group IV semiconductor, such as silicon (Si), germanium (Ge), or SiGe), a compound semiconductor (e.g., a group III-V compound semiconductor, such as GaAs or GaP, a group II-VI compound semiconductor, etc.), an oxide semiconductor, a two-dimensional material semiconductor, and/or the like. When the substrate 110, the channel 120, the source region 111, and the drain region 112 include Si, Ge, SiGe, and/or the, the substrate 110 and the channel 120 may be doped with at least one dopant from among B, Al, Ga, and In, and the source region 111 and the drain region 112 may be doped with at least one dopant from among P, As, and Sb. Then, the semiconductor device 100 becomes an n-channel metal oxide semiconductor field effect transistor (NMOS). In contrast to this, the substrate 110 and the channel 120 may be doped with at least one dopant from among P, As, and Sb, and the source region 111 and the drain region 112 may be doped with at least one dopant from among B, Al, Ga, and In. In this case, the semiconductor device 100 becomes a p-channel metal oxide semiconductor field effect transistor (PMOS).

The gate electrode 160 may have a conductivity of about 1 Mohm/square or less. The gate electrode 160 may include a conductive material. For example, the conductive material may include one or more materials selected from a metal, a metal nitride, metal carbide, polysilicon, and/or combinations thereof. For example, the metal may include aluminum (Al), tungsten (W), molybdenum (Mo), titanium (Ti), or tantalum (Ta), the metal nitride may include a titanium nitride (TiN) or a tantalum nitride (TaN), and the metal carbide may be a metal carbide doped with (or containing) aluminum or silicon and may include TiAlC, TaAlC, TiSiC, or TaSiC as a specific example. However, the examples are not limited thereto.

In at least one example, the gate electrode 160 may also have a structure in which a plurality of materials are stacked. For example, the gate electrode 160 may have a stacked structure of a metal nitride layer/metal layer, such as TiN/Al, or a stacked structure of a metal nitride layer/metal carbide layer/metal layer, such as TiN/TiAlC/W. The gate electrode 160 may include a titanium nitride (TiN) or molybdenum (Mo), and the above examples may be used in various modified forms.

In addition, the gate electrode 160 may also include a conductive two-dimensional material. For example, the conductive two-dimensional material may include at least one of graphene, black phosphorus, amorphous boron nitride, two-dimensional hexagonal boron nitride (h-BN), phosphorene, and/or the like.

The first insulating layer 131 may be formed by natural oxidation of a semiconductor material of the channel 120 (e.g., during a process of manufacturing the semiconductor device 100). Therefore, in at least one example, the first insulating layer 131 may include an oxide of a semiconductor material. For example, when the channel 120 includes Si, Ge, SiGe, etc., the first insulating layer 131 may include a corresponding one (or more) of SiO₂, GeO₂, SiGeO₄, etc.

The second insulating layer 132 may include an insulating oxide. The second insulating layer 132 may include, for example, silicon oxide. A thickness of the second insulating layer 132 may be, for example, 2 nm or more.

The ferroelectric layer 140 may include a ferroelectric material. The ferroelectric material may have ferroelectricity in which internal electric dipole moments are aligned to maintain spontaneous polarization even when no electric field is applied from the outside. In other words, the ferroelectric layer 140 may undergo spontaneous polarization in the presence of an electrical field and the polarization may be maintained when the electrical field is removed. A threshold voltage of the semiconductor device 100 may change depending on a polarization direction of the ferroelectric layer 140, for example, a direction from the gate electrode 160 toward the channel 120 or, conversely, a direction from the channel 120 toward the gate electrode 160.

The ferroelectric layer 140 may include a ferroelectric having a ferroelectric phase (e.g., a crystal structure lacking an inversion center (e.g., is non-centrosymmetric)) in the largest proportion among all crystal phases and/or as a dominant phase. For example, the ferroelectric may have at least one structure among, for example, a fluorite structure, a perovskite structure, and a wurtzite structure. In at least one example embodiment, the ferroelectric may include, for example, hafnium oxide (HfO₂) having the fluorite structure.

The ferroelectric layer 140 may include a material in which a dopant is added to a material forming the second trap layer 152. In other words, the ferroelectric layer 140 and the second trap layer 152 may both include a first material, with the ferroelectric layer 140 further including a dopant. The dopant may include, for example, at least one of zirconium (Zr), lanthanum (La), aluminum (Al), silicon (Si), and yttrium (Y). A doping concentration of the ferroelectric layer 140 may be, for example, 10 at % to 90 at %. The doping concentration of the ferroelectric layer 140 may be, for example, 25 at % to 75 at %. A thickness of the ferroelectric layer 140 may be, for example, 5 nm or more.

The charge trap layer 150 may include the first trap layer 151 and the second trap layer 152. The first trap layer 151 may include a material in which a dopant is added to a material forming the second trap layer 152. Thereby, the first trap layer 151 and the second trap layer 152 may be referred to as including a same material. The dopant may include at least one of, for example, zirconium (Zr), lanthanum (La), aluminum (Al), silicon (Si), and yttrium (Y). The composition of the first trap layer 151 may be different from the composition of the ferroelectric layer 140. More specifically, in at least one example embodiment, the dopant of the first trap layer 151 may be different from the dopant of the ferroelectric layer 140. The first trap layer 151 may be doped at a relatively high concentration. A doping concentration of the first trap layer 151 may be, for example, 50 at % or more. In such cases, the first trap layer 151 may be referred to as being “highly doped”. In at least one example embodiment, the second trap layer 152 may be an undoped layer. A thickness of the charge trap layer 150 may be, for example, 3 nm or more.

The ferroelectric layer 140, the first trap layer 151, and the second trap layer 152 may include at least one identical element except oxygen. For example, the ferroelectric layer 140, the first trap layer 151, and the second trap layer 152 may share at least one identical element in addition to oxygen. The ferroelectric layer 140, the first trap layer 151, and the second trap layer 152 may share a matrix. The ferroelectric layer 140, the first trap layer 151, and the second trap layer 152 may each include, for example, hafnium. For example, the ferroelectric layer 140 may include hafnium zirconium oxide, the first trap layer 151 may include hafnium aluminum oxide, and the second trap layer 152 may include hafnium oxide. As the ferroelectric layer 140, the first trap layer 151, and the second trap layer 152 include at least one identical element, a process may be simplified, and an interface between the ferroelectric layer 140 and the first trap layer 151, and an interface between the first trap layer 151 and the second trap layer 152 may be stabilized.

The sum of thicknesses of the ferroelectric layer 140, the first trap layer 151, the second trap layer 152, and the second insulating layer 132 may be, for example, 25 nm or less. For example, in at least one example, embodiment, the sum of thicknesses of the ferroelectric layer 140, the first trap layer 151, the second trap layer 152, and the second insulating layer 132 may be, for example, 20 nm or less.

The semiconductor device 100, according to at least one embodiment. includes the charge trap layer 150 designed to increase the amount of charge traps, and accordingly, a memory window of the semiconductor device 100 may increase.

The memory window of the semiconductor device 100 may be represented by following Equation 1.

$$MW = \frac{( Δ P - Δ {Q}_{it , I 2} )}{{C}_{Ferro}} + \frac{( Δ {Q}_{it , I 1} - Δ {Q}_{it , I 2} )}{{C}_{I 1}} \qquad Equation 1$$

In Equation 1 above, ΔP is a polarization amount of the ferroelectric layer 140, ΔQ_{it,12} is an amount of charges trapped at an interface of the ferroelectric layer 140 facing the channel 120, ΔQ_{it,11} is an amount of charges trapped at an interface of the ferroelectric layer 140 facing the gate electrode 160, C_{Ferro} is capacitance of the ferroelectric layer 140, and Cn is capacitance of layers between the gate electrode 160 and the ferroelectric layer 140. That is, when there are more charges in the additionally inserted charge trap layer 150, a memory window of the semiconductor device 100 may be expanded.

As described above, the semiconductor device 100 according to the at least one example embodiment. includes the charge trap layer 150 including the first trap layer 151 and the second trap layer 152 to increase ΔQ_{it,11}. The charge trap layer 150 may include the relatively highly doped first trap layer 151 and the undoped second trap layer 152, and accordingly, the semiconductor device 100 may have a relatively large memory window.

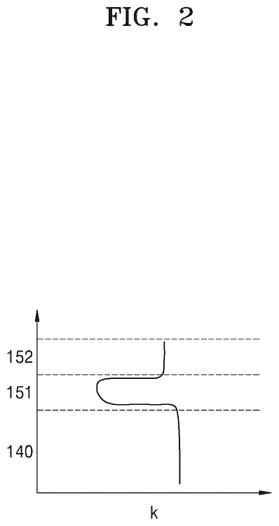

FIG. 2 is a graph schematically illustrating permittivity depending on portions of the semiconductor device according to at least one example embodiment.

Referring to FIG. 2, the permittivity of the first trap layer 151 may be less than the permittivity of the ferroelectric layer 140, and the permittivity of the first trap layer 151 may be less than the permittivity of the second trap layer 152. The first trap layer 151 may have permittivity less than permittivity of the ferroelectric layer 140 and less than permittivity of the second trap layer 152 due to the relatively high doping.

The permittivity of the second trap layer 152 may be less than permittivity of the ferroelectric layer 140. In conclusion, the permittivity of the second trap layer 152 may be less permittivity of the ferroelectric layer 140 and greater than permittivity of the first trap layer 151.

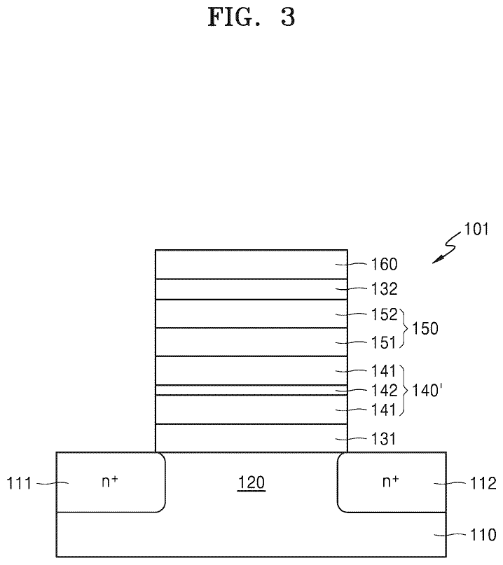

FIG. 3 is a view illustrating a semiconductor device according to at least one example embodiment.

Referring to FIG. 3, a semiconductor device 101 may include a source region 111, a drain region 112, a channel 120 between the source region 111 and the drain region 112, a gate electrode 160, a ferroelectric layer 140′ between the channel 120 and the gate electrode 160, and a charge trap layer 150. The charge trap layer 150 may include a first trap layer 151 between the ferroelectric layer 140′ and the gate electrode 160 and a second trap layer 152 between the first trap layer 151 and the gate electrode 160.

The ferroelectric layer 140′ may include a plurality of first material layers 141 and at least one second material layer 142 between two facing first material layers 141. Although FIG. 3 illustrates two first material layers 141 and one second material layer 142 as an example, the number of first material layers 141 and the second material layer 142 is not limited thereto.

The first material layers 141 may include a ferroelectric material of the ferroelectric layer 140 described in FIG. 1. The first material layers 141 may include, for example, hafnium zirconium oxide. The second material layer 142 may include a paraelectric material. For example, the second material layer 142 may include at least one paraelectric material among Al₂O₃, SiO₂, La₂O₃, and Y₂O₃.

The semiconductor device 101 may be the same as (or substantially similar to) the semiconductor device 100 illustrated in FIG. 1 except that the semiconductor device 101 includes the ferroelectric layer 140′. Therefore, in describing the components of FIG. 3, redundant descriptions thereof have been omitted.

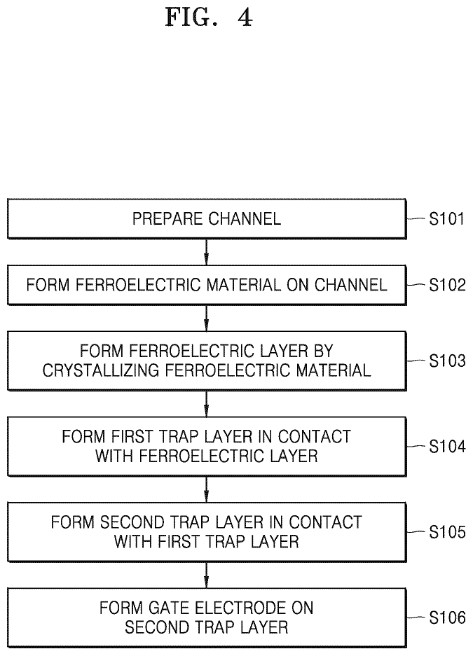

FIG. 4 is a diagram illustrating a method of manufacturing a semiconductor device, according to at least one example embodiment.

Referring to FIG. 4, a channel is prepared (S101), and a ferroelectric pre-cursor including the ferroelectric material is formed on the channel (S102). Thereafter, the ferroelectric material is crystallized to form a ferroelectric layer (S103). The ferroelectric layer may be formed using a chemical vapor deposition (CVD) process, a physical vapor deposition (PVD) process, an atomic layer deposition (ALD) process, or a combination thereof. The channel may be the same as (or substantially similar to) the channel 120 of FIG. 1. The ferroelectric layer may be the same as (or substantially similar to) the ferroelectric layer 140 of FIG. 1 or the ferroelectric layer 140′ of FIG. 3. A first insulating layer may be deposited before the ferroelectric material is deposited in the channel. The first insulating layer may be formed between the channel and the ferroelectric layer. The first insulating layer may be the same as (or substantially similar to) the first insulating layer 131 of FIG. 1.

A first trap layer in contact with the ferroelectric layer is formed (S104), and a second trap layer in contact with the first trap layer is formed (S105). The first trap layer and the second trap layer may be respectively the same as (or substantially similar to) the first trap layer 151 and the second trap layer 152 of FIG. 1.

A gate electrode is formed on the second trap layer (S106). The gate electrode may be the same as the gate electrode 160 of FIG. 1. A second insulating layer may be formed before the gate electrode is formed on the second trap layer. The second insulating layer may be formed between the second trap layer and the gate electrode. The second insulating layer may be the same as (or substantially similar to) the first insulating layer 132 of FIG. 1.

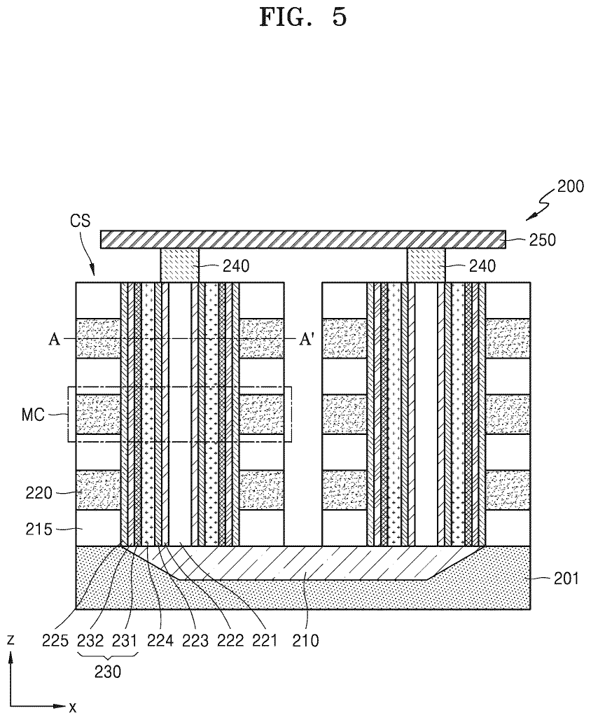

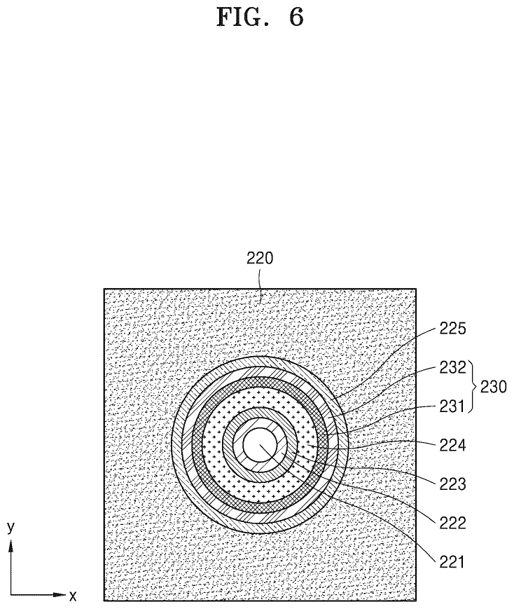

FIG. 5 is a cross-sectional view illustrating a schematic structure of a memory device according to at least one example embodiment, and FIG. 6 is a cross-sectional view taken along line A-A′ of FIG. 5. The memory device of the present example may be a charge trap-based flash NAND device.

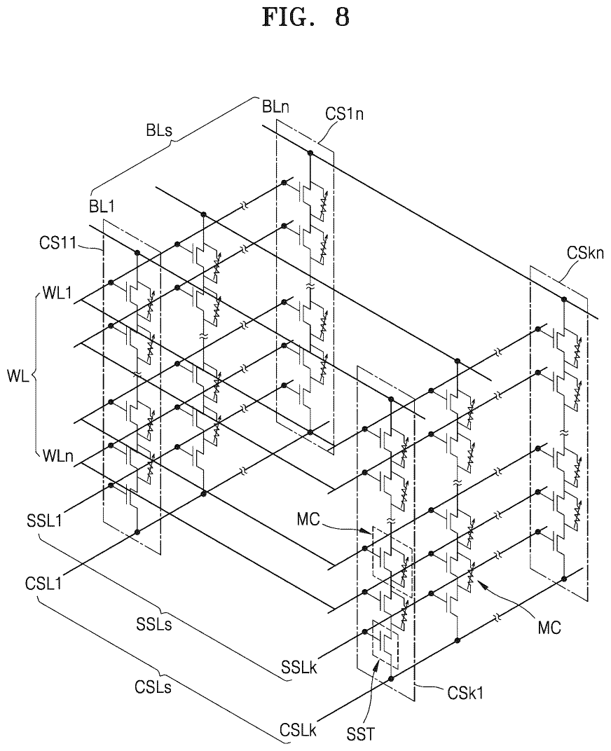

Referring to FIGS. 5 and 6, a memory device 200 may include a substrate 201, and a plurality of memory cell strings CS on the substrate 201. Although two memory cell strings CS are illustrated in FIG. 5, this is an example, and the memory device 200 may include a plurality of memory cell strings. For example, the plurality of memory cell strings CS may be arranged two-dimensionally in two directions perpendicular to a direction (the Z direction) away from the substrate 201. The plurality of memory cell strings CS may be arranged in a matrix including k*n cells as illustrated in a circuit diagram of FIG. 8 described below, and may be named CSij (1≤i≤k, 1≤j≤n) depending on each row and column position.

The substrate 201 may be a semiconductor substrate. The substrate 201 may include, for example, a silicon material doped with a first-type impurity. For example, the substrate 201 may include a silicon material doped with a p-type impurity. For example, the substrate 201 may be a p-type well (for example, a pocket p-well). However, the disclosure is not limited thereto, and the substrate 201 may include one or more semiconductor materials.

A common source region 210 may be provided in an upper portion of the substrate 201. The common source region 210 may be a different type material from the semiconductor material included in the substrate 201, for example, an n-type material. The common source region 210 may be connected to, for example, a common source line CSL illustrated in the circuit diagram of FIG. 8.

The memory cell string CS may have a circular cross-section illustrated in the cross-sectional view of FIG. 6, and for example, the memory cell string CS may have a cylindrical shape having a central axis parallel to the Z direction. However, this is an example, and the memory cell string CS may also be deformed into a shape of an oval column, an elliptical column, polygonal column, and/or the like.

A plurality of gate electrodes 220 may be separated from each other in an axial direction of the memory cell string CS, for example, the Z direction, and a spacer 215 including an insulating material may be provided between each of the plurality of gate electrodes 220.

The gate electrodes 220 and the spacers 215 may have cylindrical shell shapes respectively having inner surfaces connected to each other, and a second insulating layer 225 may be conformally formed on the inner surfaces. Next, a charge trap layer 230 may be conformally formed on a second insulating layer 360, and a ferroelectric layer 224 may be conformally formed on the charge trap layer 230. The charge trap layer 230 may include a first trap layer 231 in contact with the ferroelectric layer 224 and a second trap layer 232 in contact with the second insulating layer 225. Next, a first insulating layer 223 and a channel 222 may be conformally formed on the ferroelectric layer 224. Otherwise, the charge trap layer 230 may be substantially the same as (or substantially similar to) the charge trap layer 150 illustrated in FIG. 1.

The center of the memory cell string CS may be filled with a cylindrical insulating layer 221. However, this is an example, and the insulating layer 221 may be omitted or formed in a cylindrical shell shape.

Materials of the channel 222, the first insulating layer 223, the ferroelectric layer 224, the charge trap layer 230, the second insulating layer 225, and the gate electrode 220 may include the materials that may be included in the channel 120, the first insulating layer 131, the ferroelectric layer 140, the charge trap layer 150, the second insulating layer 132, and the gate electrode 160 described with reference to FIG. 1.

One end of the channel 222, that is, a region of the channel 222 which is located at the bottom of the memory cell string CS, may be in contact with the common source region 210.

A drain 240 may be on the memory cell string CS. The drain 240 may include, for example, a silicon material doped with an n type. The other end of the channel 222, that is, a region of the channel 222 which is located at the top of the memory cell string CS, may be in contact with the drain 240. The drain 240 may be connected to a bit line 250 through contact plugs.

The gate electrode 220, and the second insulating layer 225, charge trap layer 230, ferroelectric layer 224, first insulating layer 223 and channel 222 facing the gate electrode 220 constitute a memory cell MC.

A plurality of memory cells MC are arranged continuously in a vertical direction (the Z direction) to constitute the memory cell string CS. In addition, the common source region 210 and the drain 240 respectively connected to both ends of the memory cell string CS may be connected to the common source line CSL and a bit line BL illustrated in the circuit diagram of FIG. 8. The gate electrode 220 is connected to a word line WL. By applying a voltage to the word line WL, the common source line CSL, and the bit line BL, programming, reading, and erasing process may be performed on the plurality of memory cells MC.

The ferroelectric layer 224 is a material in which a polarization value remains semi-permanently within the material even after a certain voltage is applied thereto and the voltage decreases to 0 V, and a polarity (direction) of the residual polarization may depend on a polarity (direction) of an externally applied voltage. A region of the ferroelectric layer 224 corresponding to each memory cell MC may have a residual polarization corresponding to an electric field formed within the ferroelectric layer 224 by a voltage applied to the gate electrode 220. Due to the polarization direction of the ferroelectric layer 224, a difference in conductivity may occur in a region of the channel 222 corresponding to the corresponding memory cell MC, and information may be written or read therethrough.

In addition, the memory device 200 may include the first trap layer 231 that is heavily doped and the second trap layer 232 that is not doped such that a memory window is increased, and accordingly, the reliability of a memory operation may be improved.

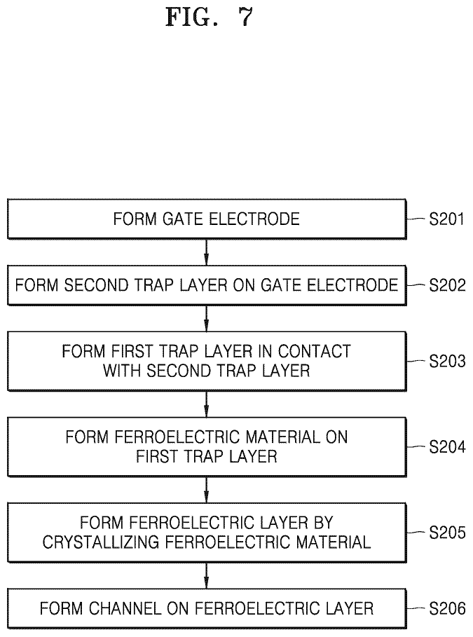

FIG. 7 is a flowchart illustrating a method of manufacturing a memory device, according to another embodiment.

Referring to FIG. 7, a gate electrode is formed (S201), a second trap layer is formed on the gate electrode (S202), and a first trap layer in contact with the second trap layer is formed (S203). The gate electrode may be the same as (or substantially similar to) the gate electrode 220 of FIG. 5. The first trap layer and the second trap layer may be the same as (or substantially similar to) the first trap layer 231 and the second trap layer 232 of FIG. 5. A second insulating layer may be formed before the second trap layer is formed on the gate electrode. The second insulating layer may be formed between the second trap layer and the gate electrode. The second insulating layer may be the same as (or substantially similar to) the second insulating layer 225 of FIG. 5.

A ferroelectric material is formed in the first trap layer (S204), and the ferroelectric material is crystallized to form a ferroelectric layer (S205). The ferroelectric layer may be formed by a CVD process, a PVD process, an ALD process, or a combination thereof. The ferroelectric layer may be the same as the ferroelectric layer 224 of FIG. 5.

A channel is formed on the ferroelectric layer (S205). The channel may be the same as (or substantially similar to) the channel 222 of FIG. 5. A first insulating layer may be deposited before the channel is deposited on the ferroelectric layer. The first insulating layer may be formed between the channel and the ferroelectric layer. The first insulating layer may be the same as (or substantially similar to) the first insulating layer 223 of FIG. 5.

FIG. 8 is a diagram illustrating an equivalent circuit of a memory device according to at least one example embodiment.

Referring to FIG. 8, the memory device may include a plurality of memory cell strings CSl1 to CSkn. The plurality of memory cell strings CSl1 to CSkn may be two-dimensionally arranged in a row direction and a column direction to form rows and columns. A memory cell string CSij (1≤i≤k, 1≤j≤n) may be connected to a bit line BL, a string select line SSL, a word line WL, and a common source line CSL.

The memory cell string CSij may include memory cells MC and a string select transistor SST. The memory cells MC and the string select transistor SST of each memory cell string CSij may be stacked in a height direction.

Rows of the plurality of memory cell strings CSl1 to CSkn may be respectively connected to different string select lines SSL1 to SSLk from each other. For example, string select transistors SST of the memory cell strings CSl1 to CSln are commonly connected to the string select line SSL1. String select transistors SST of the memory cell strings CSk1 to CSkn are commonly connected to the string select line SSLk.

Columns of the plurality of memory cell strings CSl1 to CSkn are respectively connected to different bit lines BL1 to BLn from each other. For example, the memory cells MC and the string select transistors SST of the memory cell strings CSl1 to CSk1 may be commonly connected to the bit line BL1, and the memory cells MC and the string select transistors SST of the memory cell strings CSln to CSkn may be commonly connected to the bit lines BLn.

Rows of the plurality of memory cell strings CSl1 to CSkn may be respectively connected to different common source lines CSL1 to CSLk from each other. For example, the string select transistors SST of the memory cell strings CSl1 to CSln may be commonly connected to the common source line CSL1, and the string select transistors SST of the memory cell strings CSK1 to CSkn may be commonly connected to the common source line CSLk.

The string select transistors SST or the memory cells MC located at the same height from the substrate 201 of FIG. 5 may be commonly connected to one of the word lines WL1 to WLm, and the memory cells MC located at different heights from each other may be respectively connected to different word lines WL1 to WLm from each other.

In this structure, writing and reading may be performed in units of rows of the memory cell strings CSl1 to CSkn. For example, the plurality of memory cell strings CSl1 to CSkn may be selected in units of rows by the common source lines CSLs, and the plurality of memory cell strings CSl1 to CSkn may be selected in units of rows by the string select lines SSLs. In addition, in the selected rows of the plurality of memory cell strings CSl1 to CSkn, writing and reading may be performed in units of pages. For example, the page may be one row of the memory cells MC connected to one word line WL. In the selected rows of the plurality of memory cell strings CSl1 to CSkn, the memory cells MC may be selected in units of pages by word lines WL.

The illustrated circuit structure is an example. For example, the number of rows of the memory cell string CSij (1≤i≤k, 1≤j≤n) may be increased or decreased. As the number of rows of the plurality of memory cell strings CSl1 to CSkn changes, the number of string select lines SSL1 to SSLk connected to the rows of the plurality of memory cell string CSl1 to CSkn and the number of memory cell strings connected to one bit line BL may also change. As the number of rows of the plurality of memory cell strings CSl1 to CSkn changes, the number of common source lines CSL1 to CSLk connected to the rows of the memory cell strings CSl1 to CSkn may also change.

The number of columns of the plurality of memory cell strings CSl1 to CSkn may also increase or decrease. As the number of columns of the plurality of memory cell strings CSl1 to CSkn changes, the number of bit lines BLs connected to the columns of the plurality of memory cell strings CSl1 to CSkn and the number of memory cell strings CSij connected to one string select line may also change.

A height of the memory cell string CSij may also increase or decrease. For example, the number of memory cells MC stacked in the memory cell string CSij may increase or decrease. As the number of memory cells MC stacked in the memory cell string CSij changes, the number of word lines WL may also change. For example, the number of string select transistors provided in the plurality of memory cell strings CSl1 to CSkn may increase. As the number of string select transistors provided in the plurality of memory cell strings CSl1 to CSkn changes, the number of string select lines or common source lines may also change. As the number of string select transistors increases, the string select transistors may be stacked in the same form as the memory cells MC.

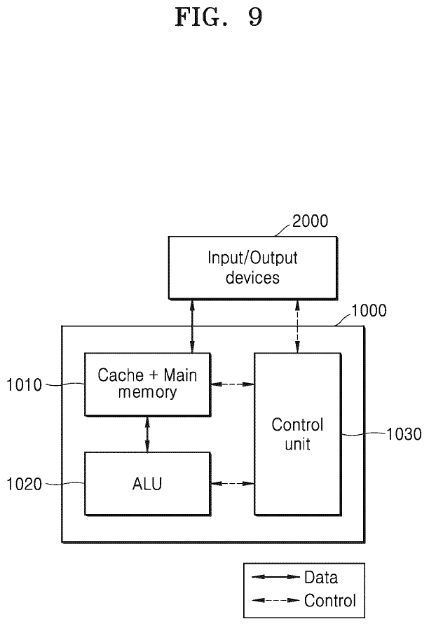

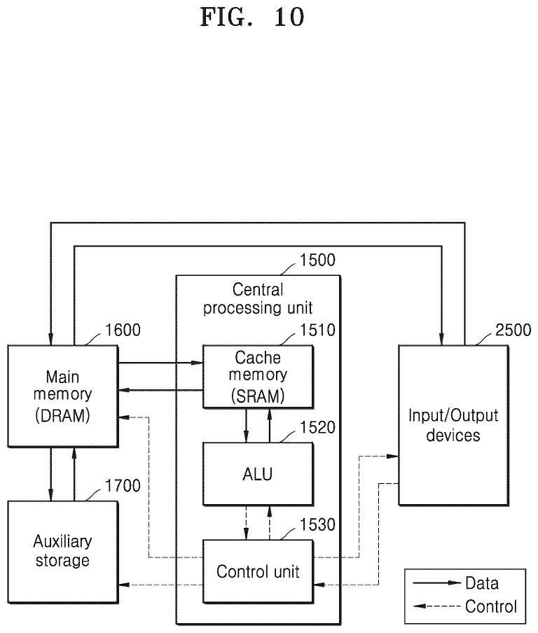

FIGS. 9 and 10 are conceptual diagrams schematically illustrating an electronic component architecture, which may be applied to an electronic device, according to at least some example embodiments.

Referring to FIG. 9, an electronic component architecture 1000 may include a memory unit 1010, an arithmetic logic unit (ALU) 1020, and a control unit 1030. The memory unit 1010, the ALU 1020, and the control unit 1030 may be electrically connected to each other. For example, the electronic component architecture 1000 may be implemented as a single chip including the memory unit 1010, the ALU 1020, and the control unit 1030.

Specifically, the memory unit 1010, the ALU 1020, and the control unit 1030 may be interconnected by metal lines in an on-chip and may directly communicate to each other. The memory unit 1010, the ALU 1020, and the control unit 1030 may be monolithically integrated on a single substrate to form a single chip. The electronic device architecture (chip) 1000 may be connected to an input/output device 2000.

The ALU 1020 and the control unit 1030 may each include the semiconductor device 100 or 101 and/or the memory device 200 described above, and the memory unit 1010 may include the semiconductor device 100 or 101 and/or the memory device 200 described above, a capacitor, or a combination thereof. The memory unit 1010 may include both a main memory and a cache memory. The electronic component architecture (chip) 1000 may be an on-chip memory processing unit.

Referring to FIG. 10, a cache memory 1510, an ALU 1520, and a control unit 1530 may constitute a central processing unit (CPU) 1500. The cache memory 1510 may include a static random access memory (SRAM) and may include the semiconductor device 100 or 101 and/or the memory device 200 described above. The electronic component architecture may include a main memory 1600 and auxiliary storage 1700 in addition to the CPU 1500. The main memory 1600 may include a dynamic random access memory (DRAM) device.

In some cases, an electronic device architecture may be implemented in a form in which computing unit devices are adjacent to memory unit devices within one chip without distinction of sub-units.

The semiconductor device according to the disclosure includes various memory devices, such as DRAM, SRAM, NAND flash memory, NOR flash memory, phase-change random access memory (PRAM), magnetoresistive random access memory (MRAM), and resistive random access memory (ReRAM) but is not limited thereto.

The semiconductor device and the method of manufacturing the same according to the disclosure may increase a memory window and improve thermal stability. Although the semiconductor device and the method of manufacturing the semiconductor device are described with reference to the embodiments illustrated in the drawings, these are merely examples, and those skilled in the art will understand that various modifications and equivalent other embodiments may be derived therefrom. Therefore, the disclosed embodiments should be considered from an illustrative rather than a restrictive perspective. The scope of the rights is indicated in the claims, not in the foregoing description, and all differences within the scope equivalent thereto should be construed as being included in the scope of the rights.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel;
a gate electrode;
a ferroelectric layer between the channel and the gate electrode; and
a charge trap layer including a first trap layer and a second trap layer, the first trap layer between the ferroelectric layer and the gate electrode, and the second trap layer between the first trap layer and the gate electrode,
wherein the first trap layer, the second trap layer, and the ferroelectric layer include at least one identical element other than oxygen.

2. The semiconductor device of claim 1, wherein the second trap layer includes a first material, and
the ferroelectric layer includes the first material and a dopant.

3. The semiconductor device of claim 2, wherein the dopant includes at least one of zirconium (Zr), lanthanum (La), aluminum (Al), silicon (Si), or yttrium (Y).

4. The semiconductor device of claim 2, wherein a doping concentration of the ferroelectric layer is 10 at % to 90 at %.

5. The semiconductor device of claim 1, wherein the second trap layer includes a first material, and
the first trap layer includes the first material and a dopant.

6. The semiconductor device of claim 5, wherein the dopant includes at least one of zirconium (Zr), lanthanum (La), aluminum (Al), silicon (Si), or yttrium (Y).

7. The semiconductor device of claim 5, wherein a doping concentration of the first trap layer is 50 at % or more.

8. The semiconductor device of claim 1, wherein the ferroelectric layer and the first trap layer have different dopants.

9. The semiconductor device of claim 1, wherein
the ferroelectric layer includes a plurality of first material layers and at least one second material layer, the at least one second material layer between two of the plurality of first material layers which are facing each other,
wherein each of the plurality of first material layers includes a ferroelectric material, and
wherein the at least one second material layer includes a paraelectric material.

10. The semiconductor device of claim 1, wherein a thickness of the ferroelectric layer is greater than a thickness of the charge trap layer.

11. The semiconductor device of claim 1, further comprising:
a first insulating layer between the channel and the ferroelectric layer.

12. The semiconductor device of claim 1, further comprising:
a second insulating layer between the charge trap layer and the gate electrode.

13. The semiconductor device of claim 1, wherein the first trap layer, the second trap layer, and the ferroelectric layer each include hafnium.

14. The semiconductor device of claim 1, wherein
the ferroelectric layer includes hafnium zirconium oxide,
the first trap layer includes hafnium aluminum oxide, and
the second trap layer includes hafnium oxide.

15. A semiconductor device comprising:
a channel;
a gate electrode;
a ferroelectric layer between the channel and the gate electrode; and
a charge trap layer including a first trap layer and a second trap layer, the first trap layer between the ferroelectric layer and the gate electrode, and the second trap layer between the first trap layer and the gate electrode,
wherein a permittivity of the first trap layer is less than a permittivity of the ferroelectric layer and the permittivity of the first trap layer is less than a permittivity of the second trap layer.

16. The semiconductor device of claim 15, wherein the permittivity of the second trap layer is less than the permittivity of the ferroelectric layer.

17. The semiconductor device of claim 15, further comprising:
a first insulating layer between the channel and the ferroelectric layer.

18. The semiconductor device of claim 15, further comprising:
a second insulating layer between the charge trap layer and the gate electrode.

19. The semiconductor device of claim 15, wherein the first trap layer, the second trap layer, and the ferroelectric layer each include hafnium.

20. The semiconductor device of claim 15, wherein
the ferroelectric layer includes hafnium zirconium oxide,
the first trap layer includes hafnium aluminum oxide, and
the second trap layer includes hafnium oxide.
